(19) United States
(12) Patent Application Publication
(10) Pub. No.: US 2014/0287593 A1
(43) Pub. Date: Sep. 25, 2014

(54) HIGH THROUGHPUT MULTI-LAYER STACK DEPOSITION

(71) Applicant: APPLIED MATERIALS, INC., Santa Clara, CA (US)

(72) Inventors: Xinhai HAN, Fremont, CA (US); Zhijun JIANG, Sunnyvale, CA (US); Nagarajan RAJAGOPALAN, Santa Clara, CA (US); Bok Hoen KIM, San Jose, CA (US); Ramprakash SANKARAKRISHNAN, Santa Clara, CA (US); Ganesh BALASUBRAMANIAN, Sunnyvale, CA (US); Juan Carlos ROCHA- ALVAREZ, San Carlos, CA (US); Mukund SRINIVASAN, Fremont, CA (US)

(21) Appl. No.: 14/218,103

(22) Filed: Mar. 18, 2014

Related U.S. Application Data
(60) Provisional application No. 61/804,017, filed on Mar. 21, 2013.

(51) Int. Cl. H01L 21/02

(52) U.S. Cl. CPC H01L 21/02274; H01L 21/02164; H01L 21/0217; H01L 21/02211
USPC 438/763; 118/715; 118/723 R

(57) ABSTRACT

Methods and apparatus for high rate formation of multi-layer stacks on semiconductor substrate is provided. A chamber for forming such stacks at high rates includes a first precursor line and a second precursor line. The first precursor line is coupled to a first diverter, which is coupled to a gas inlet in a lid assembly of the chamber. The second precursor line is coupled to a second diverter, which is also coupled to the gas inlet. The first diverter is also coupled to a first divert line, and the second diverter is coupled to a second divert line. Each of the first and second divert lines is coupled to a divert exhaust system. A chamber exhaust system is coupled to the chamber. The diverters are typically located close to the lid assembly.

### CROSS-REFERENCE TO RELATED APPLICATIONS

This application claims benefit of U.S. Provisional Patent Application Ser. No. 61/804,017 filed Mar. 21, 2013, which is incorporated herein by reference.

### FIELD

Embodiments of the present invention generally relate to semiconductor manufacturing apparatus and methods. Specifically, embodiments described herein relate to chemical vapor deposition chambers having high rate deposition features.

### BACKGROUND

For over 50 years, the number of transistors formed on an integrated circuit has doubled approximately every two years. This two-year-doubling trend, also known as Moore's Law, is projected to continue, with devices formed on semiconductor chips shrinking from the current critical dimension of 20-30 nm to below 100 Angstroms in future fabrication processes currently being designed. As device geometries shrink, substrate sizes also grow. As the 300 mm wafer replaced the 200 mm wafer years ago, the 300 mm wafer may be replaced by the 400 mm or 450 mm wafer.

Uniformity in processing conditions has always been important to semiconductor manufacturing, and as critical dimensions of devices continue to shrink the need for precision increases, and as substrate size increases, the likelihood of non-uniformity increases. Non-uniformity arises from numerous causes, which may be related to device properties, equipment features, and the chemistry and physics of fabrication processes. As the semiconductor manufacturing industry progresses along Moore's Law, there is a continuing need for fabrication processes and equipment capable of very uniform processing.

As device dimensions continue to shrink, and the two-dimensional limitations of Moore's Law become insurmountable, manufacturers are turning to three-dimensional structures to propel future growth. Devices such as FINFETs and three-dimensional memory devices such as DRAM and VNAND devices typically feature layers of different materials in a stack. Multiple devices or cells may be stacked one atop the other, and several devices are typically formed on one substrate. The layers are often different materials, so one structure may contain alternating layers of insulating, semi-conducting, and metallic layers such as SiO₂, SiN, a-Si, and poly-Si. Typically the stack consists of 32 or 64, or even 128 layers of these alternating layers. The electrical properties of such devices depend on the thickness and composition of the various layers, so non-uniformity in the thickness and/or composition of the layers leads to non-uniformity in performance. Non-uniformity within a single device can render the device inoperative, and non-uniformity from device to device leads to different devices having different electrical properties, sometimes substantially different.

For such structures to be cost-effectively produced, it is often advantageous for some or all of the layers to be formed in a single chamber or a small number of chambers, so that one chamber is forming several layers, potentially of several different materials using different chemistries. A first layer is formed using a first precursor mixture. Following formation of the first layer, the first precursor mixture is flushed from the chamber to avoid cross-contamination. A second precursor mixture is then used to form a second layer. Normally, if plasma processing is involved, plasma is discontinued during the flush operation and reestablished when flow of the second precursor mixture stabilizes. Arcing and particle formation may occur from an unstable plasma. The interruption in deposition to flush and purge the chamber reduces throughput.

There is a need for apparatus and methods that can form multi-layer stacks at high rates.

### SUMMARY OF THE INVENTION

Methods and apparatus for high rate formation of multi-layer stacks on semiconductor substrate is provided. A chamber for forming such stacks at high rates includes a first precursor line and a second precursor line. The first precursor line is coupled to a first diverter, which is coupled to a gas inlet in a lid assembly of the chamber. The second precursor line is coupled to a second diverter, which is also coupled to the gas inlet. The first diverter is also coupled to a first divert line, and the second diverter is coupled to a second divert line. Each of the first and second divert lines is coupled to a divert exhaust system. A chamber exhaust system is coupled to the chamber. The diverters are typically located close to the lid assembly.

The apparatus described herein may be used to form multi-layer stacks at high rates. A method of forming a multi-layer stack on a substrate includes disposing the substrate on a substrate support in a processing chamber, flowing a first precursor mixture through a first pathway to a first diverter coupled to a gas inlet of the chamber, flowing a second precursor mixture through a second pathway to a second diverter coupled to the gas inlet, forming a first reaction mixture from the first precursor mixture and the second precursor mixture in the processing chamber, coupling RF power to the first reaction mixture to form a plasma in the processing chamber, forming a first film on the substrate from the plasma, maintaining the plasma, diverting the first precursor to a divert line by operating the first diverter, discontinuing the second precursor, flowing a third precursor mixture through the second pathway to the processing chamber, flowing a fourth precursor mixture through the first pathway to the divert line, directing the fourth precursor to the process chamber by operating the first diverter, and forming a second film on the first film. Compounds in the precursor mixtures may be selected to avoid spontaneous reactions in the event of contact between any precursor compounds.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic side view of an apparatus according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Apparatus and methods are described for forming multi-layer stacks on semiconductor substrates. Plasma processing is used to form each layer of the stack, and the process is transitioned from forming a first layer to forming a second layer while maintaining the plasma and minimizing cross-contamination between the two layers. Precursor lines are coupled to a processing chamber for delivering precursor gas mixtures to the chamber. Each precursor line has a diverter located close to the processing chamber to facilitate switching of precursors with minimal cross-contamination. A separate exhaust system is provided for the processing chamber and for the divert lines.

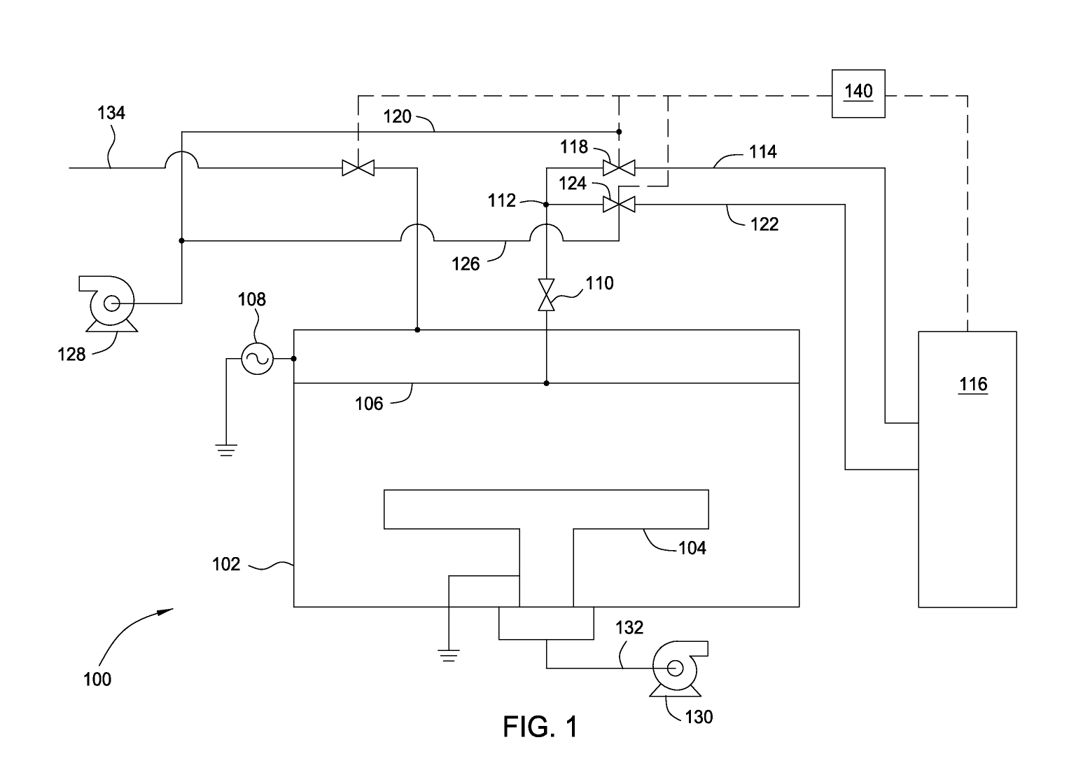

FIG. 1 is a schematic side view of an apparatus 100 according to one embodiment. A processing chamber 102 contains a substrate support 104 and a lid assembly 106 opposite the substrate support 104. The lid assembly 106 may be, or may contain, an electrode coupled to a source of plasma power 108, which may be an RF source. A gas inlet 110 is coupled to the lid assembly. A gas line 112 is coupled to the gas inlet 110. A first precursor line 114 is coupled to a gas box 116 and to the gas line 112. The first precursor line 114 has a first diverter 118 that couples the first precursor line 114 to a first divert line 120. A second precursor line 122 is coupled to the gas box 116 and to the gas line 112. The second precursor line 122 has a second diverter 124 that couples the second precursor line 122 to a second divert line 126. The first and second divert lines 120/126 are coupled to a divert exhaust system 128 dedicated to removing precursors through the divert lines 120/126. A chamber exhaust system 130 is coupled to the processing chamber 102 by an exhaust line 132 to evacuate the chamber interior. Providing a separate exhaust system for the divert lines reduces flow restriction and flow backup in the exhaust line 132 from flowing diverted gases into the exhaust line 132.

The diverters 118/124 are located as close to the lid assembly 106 as possible. In one embodiment, a flow path from any diverter to the gas inlet is less than about 3 inches. More than one gas inlet may be used, if needed. For example, a utility gas line 134 may be provided through a second gas inlet. The utility gas line 134 may be used to provide plasma forming gases and/or flush, purge, or dilution gases to the chamber 102. Locating diverters close to the gas inlet of the processing chamber provides a capability to switch precursor gases in the precursor lines with minimal cross-contamination by diverting flow in the precursor line while flow of a different mixture is established.

The apparatus 100 may be used to perform high-rate deposition of multi-layer stacks on a substrate. The substrate is disposed on the substrate support 102. Flow of a first precursor mixture is established in the first precursor line 114. At the start of the process, the diverters 118 and 124 may be lined up to flow precursors into the chamber 102. Flow of a second precursor mixture is established in the second precursor line 122. The first and second precursors are selected to react in the chamber to form a layer on the substrate. The layer may be a silicon oxide layer, a silicon nitride layer, or any layer to be deposited as part of a multi-layer stack. Pressure and temperature are established in the processing chamber. Spacing of the substrate support 104 from the lid assembly 106 is established, typically less than about 300 mils, for example about 200 mils. Pressure is between about 5 Torr and about 10 Torr, such as about 6 Torr. The narrow spacing promotes a smooth surface on the deposited layer, and the pressure maintains a desired stress in the deposited layer. Any convenient spacing and pressure may be used to form layers having different characteristics. Temperature is typically between about 250° C. and about 500° C., for example about 300° C., but any convenient temperature may be used.

Plasma may be established before or after establishing precursor flow into the chamber. A plasma forming gas may be provided to the chamber through a precursor line prior to starting flow of the other precursors, and electric power applied to the lid assembly from the source of plasma power 108 to form a plasma. The other precursor flows may then be started into the chamber while maintaining the plasma. Conversely, the precursor flows may be established and then power may be applied to the lid assembly. When RF power is used, a typical frequency of RF is 13.56 MHz, which may be mixed with a low frequency power at, for example, 300 KHz. The substrate support 104 may be coupled to ground.

A first layer is formed on the substrate under plasma processing conditions. After formation of the first layer is complete, plasma may be maintained by flowing a plasma forming gas, such as argon or helium, through the utility gas line 134. Precursor flows in the two precursor lines 122 and 114 may be diverted to the divert lines 120 and 126. Active species will begin flushing out of the chamber 102 when the precursor flows are diverted. If desired, a getter may be provided through one of the precursor lines and the diverter for that line switched to flow into the chamber. The getter may help speed reduction of active species in the chamber to provide faster transition. For example, when deposition of an oxide layer is complete, hydrogen may be provided to the chamber as a getter to speed reduction of active species in the chamber.

To form the second layer on the first layer, flow of a third precursor mixture may be established in the first precursor line 114 while the first diverter 118 is line up to the first divert line 120, and flow of a fourth precursor may be established in the second precursor line 122 while the second diverter 124 is lined up to the second divert line 126. Plasma conditions are maintained inside the chamber 102 at this time. When flow of the third and fourth precursor mixtures is established, and the chamber 102 is sufficiently purged, the diverters 118 and 124 are switched to direct flow of the third and fourth precursor mixtures into the chamber 102 to begin deposition of the second layer. Using flow diversion means, active species getters, and plasma maintaining gases in this way, significant transition time may be saved by not having to turn plasma off and on and by speeding chamber pumpdown and purge activities. A controller 140 may be provided to control gas flows from the gas box 116, utility gas flowing through the utility gas line 134, and diverters 118/124. The diversion, gettering, and gas switching may be repeated, while maintaining a plasma discharge in the chamber, to deposit a multi-layer stack on a substrate at high throughput.

Cross-contamination risk and particle risk may be further managed by selecting precursors that do not spontaneously react with each other. For example, an oxide layer may be formed by providing TEOS (tetraethyl orthosilicate) through the first precursor line and an oxidizing gas through the second precursor line, and a nitride layer may be formed by providing silane or disilane through the first precursor line and a mixture of ammonia and nitrogen through the second precursor line. Use of nitrogen oxides such as NO, N₂O, N₃O, and other nitrogen oxides, H₂O, CO₂, and other oxidizing gases that do not spontaneously react may reduce the risk of dusting in the event an oxidizing gas contacts the silane or disilane.

While the foregoing is directed to embodiments of the present invention, other and further embodiments of the invention may be devised without departing from the basic scope thereof, and the scope thereof is determined by the claims that follow.

1. An apparatus for processing a semiconductor substrate, comprising:
a chamber;
a substrate support disposed in the chamber;
a lid assembly opposite the substrate support;
a gas inlet disposed through the lid assembly;
a gas line coupled to the gas inlet;
a first diverter coupled to the gas line;
a first precursor line coupled to the first diverter;
a first divert line coupled to the first diverter;
a second diverter coupled to the gas line;
a second precursor line coupled to the second diverter;
a second divert line coupled to the second diverter;
a first exhaust system coupled to the chamber; and
a second exhaust system coupled to the first divert line and the second divert line.

2. The apparatus of claim 1, further comprising a utility gas line coupled to the lid assembly.

3. The apparatus of claim 1, wherein the lid assembly is coupled to a source of plasma power.

4. The apparatus of claim 1, wherein a flow path from each of the first and second diverters to the gas inlet is less than about 3 inches.

5. The apparatus of claim 1, further comprising a gas box coupled to the first precursor line and the second precursor line.

6. The apparatus of claim 2, further comprising a gas source coupled to the utility gas line, the gas source being selected from the group consisting of a plasma forming gas, a flush gas, a purge gas, a dilution gas, and a getter.

7. The apparatus of claim 3, wherein the source of plasma power is an RF source.

8. A method of forming a multi-layer stack on a substrate, comprising:
disposing the substrate on a substrate support in a processing chamber;
flowing a first precursor mixture through a first pathway to a first diverter coupled to a gas inlet of the chamber;
flowing a second precursor mixture through a second pathway to a second diverter coupled to the gas inlet;
forming a first reaction mixture from the first precursor mixture and the second precursor mixture in the processing chamber;
coupling RF power to the first reaction mixture to form a plasma in the processing chamber;
forming a first film on the substrate from the plasma;
maintaining the plasma while diverting the first precursor to a divert line by operating the first diverter, discontinuing the second precursor, flowing a third precursor mixture through the second pathway to the processing chamber, flowing a fourth precursor mixture through the first pathway to the divert line, and directing the fourth precursor to the process chamber by operating the first diverter; and
forming a second film on the first film.

9. The method of claim 8, wherein maintaining the plasma comprises flowing a plasma maintaining gas through a utility gas line into the processing chamber.

10. The method of claim 8, wherein the first precursor mixture comprises tetraethyl orthosilicate and the second precursor mixture comprises an oxidizing gas.

11. The method of claim 10, wherein the oxidizing gas comprises a substance selected from the group consisting of H₂O, CO₂, and a nitrogen oxide.

12. The method of claim 11, wherein the nitrogen oxide is NO, N₂O, or N₃O.

13. The method of claim 8, wherein the first precursor mixture comprises a silane gas and the second precursor mixture comprises a nitrogen source.

14. The method of claim 13, wherein the silane gas is silane or disilane and the nitrogen source comprises ammonia or nitrogen gas.

15. The method of claim 8, wherein maintaining the plasma comprises flowing a getter through a utility gas line into the processing chamber.

16. The method of claim 8, wherein the second film is different from the first film.

17. The method of claim 16, wherein the first film is an oxide film and the second film is a nitride film.

18. The method of claim 8, wherein flowing the third precursor through the second pathway to the processing chamber comprises establishing flow of the third precursor through the second divert line and switching the second diverter to direct flow of the third precursor through the second pathway to the processing chamber.
